(19) United States
(12) Patent Application Publication
(10) Pub. No.: US 2026/0169050 A1
(43) Pub. Date: Jun. 18, 2026

(54) HIGH-SPEED LOCATION METHOD FOR HIGH IMPEDANCE FAULT IN DISTRIBUTION NETWORK

(71) Applicants: Changzhou Institute of Technology, Changzhou (CN); Hohai University, Nanjing (CN)

(72) Inventors: Zhihua YIN, Changzhou (CN); Sheng CHEN, Changzhou (CN); Haixiang ZANG, Changzhou (CN); Guoqiang SUN, Changzhou (CN); Zhinong WEI, Changzhou (CN); Xiaoyong YU, Changzhou (CN); Jimin CHAI, Changzhou (CN); Haihan YE, Changzhou (CN)

(21) Appl. No.: 19/024,697

(22) Filed: Jan. 16, 2025

(30) Foreign Application Priority Data
Dec. 13, 2024 (CN) 2024118375763

(51) Int. Cl. G01R 31/08

(52) U.S. Cl. CPC G01R 31/088; G01R 31/086

(57) ABSTRACT

The present application relates to the technical field of power system fault detection, discloses a high-speed location method for high impedance fault in distribution network based on directional frequency scanning. The high-speed location method includes, intercepting a zero-sequence current signal I₀ⱼ collected by each of monitoring points of the distribution network and a bus zero-sequence voltage signal U0 of the distribution network, determining the fault occurrence time tf, extracting a first natural mode function to directly reconstruct a original fault signal, projecting a first natural mode function signal to the reference orthogonal vector group respectively, distinguishing the upstream and downstream of a fault point by a clustering algorithm. The method of constructing virtual reference direction by orthogonal vector group does not need to install voltage transformers at all measuring points, thus reducing hardware investment and maintenance costs, reducing dependence on physical hardware and greatly improving fault detection speed.

### CROSS-REFERENCE TO RELATED APPLICATIONS

This application claims priority to Chinese Patent Application No. 202411837576.3, titled “HIGH-SPEED LOCATION METHOD FOR HIGH IMPEDANCE FAULT IN DISTRIBUTION NETWORK”, filed on Dec. 13, 2024, the entire disclosure of which is incorporated herein by reference.

### TECHNICAL FIELD

The present application relates to the technical field of power system fault detection, and in particular to a high-speed location method for high impedance fault in distribution network based on directional frequency scanning.

### BACKGROUND

High impedance fault in distribution network is one of the most common and difficult fault types to detect. This kind of fault is usually manifested as a very weak current signal, which is often only in the order of several amperes, and is easily concealed by various noise signals in the distribution network. Therefore, it is a great challenge in the operation and maintenance of distribution network to accurately extract the characteristics of high impedance fault and quickly locate the fault location.

Traditional methods usually rely on the measurement data of current and voltage transformers, and identify and locate the fault point through centralized calculation. However, these methods are not stable enough to extract fault features because of their sensitivity to noise. In addition, a large number of measurement data need to be transmitted to the main station for centralized processing, which not only increases the burden of data transmission, but also brings a large delay, which is difficult to meet the requirements of rapid response to faults, and installing expensive voltage transformers at all measuring points will lead to a large amount of hardware investment and expensive maintenance costs.

### SUMMARY

This application addresses the limitations of current technology by presenting a space vector projection method, aiming at solving the problem that the traditional method usually relies on the measurement data of current and voltage transformers at the same time, and installing expensive voltage transformers at all measuring points will lead to a large amount of hardware investment and expensive maintenance costs.

In the first aspect, the present application adopts the following technical solutions.

A high-speed location method for high impedance fault in distribution network based on directional frequency scanning, including:
S1, collecting signal: intercepting a zero-sequence current signal I₀ⱼ collected by each of monitoring points of the distribution network and a bus zero-sequence voltage signal U₀ of the distribution network, wherein j is a corresponding serial number of the monitoring points, [t_{f}−T, t_{f}+5T] is an interception time of the zero-sequence current signal, t_{f} is a fault occurrence time, and T is a power frequency cycle of the power network;
S2, determining the fault occurrence time: determining the fault occurrence time t_{f} by analyzing the bus zero-sequence voltage signal U₀;
S3, decomposing discrete Fourier and reconstructing a fault characteristic signal: using the discrete Fourier decomposition to construct a directional frequency scanning strategy for the zero-sequence current signal I₀ⱼ collected by the monitoring points, and extracting a first natural mode function to directly reconstruct a original fault signal;
S4, constructing and projecting a feature vector: constructing a reference orthogonal vector group in a high-dimensional space, and projecting a first natural mode function signal to the reference orthogonal vector group respectively to generate a three-dimensional feature vector; and
S5, fusing feature and clustering analysis: distinguishing the upstream and downstream of a fault point by a clustering algorithm and locating a fault area by a clustering result based on the feature vector of a plurality of time scales.

In an embodiment, in the S2 step, the determination of the fault occurrence time includes:
S201, taking the time stamp tₛₑₜ corresponding to the sampling sequence number satisfying U₀=0.15Uₙ for the first time as a benchmark; and
S202, in the bus zero-sequence voltage sampling sequence before 100T of tₛₑₜ, the sampling point that first satisfies the following conditions is reverse searched and designated as t_{f}:

$$\vert U ( z ) - U ( z - 4 ) \vert < 9 \&\& \vert U ( z - 15 ) - U ( z - 30 ) \vert < 4$$

wherein U(z) is a discrete sampling value of the bus zero-sequence voltage, z is a index number of the corresponding sampling time, U(z−4) is the discrete sampling value of bus zero-sequence voltage with the corresponding index number z−4, U(z−15) is the discrete sampling value of bus zero-sequence voltage with corresponding index number z−15, and U(z−30) is the discrete sampling value of bus zero-sequence voltage with corresponding index number z−30.

In an embodiment, the decomposing discrete Fourier includes: performing Fourier expansion on discrete time series I₀ⱼ[n] with length N:

$${I}_{0 j} [ n ] = DFT ( {I}_{0 j} [ 0 ] ) = {\sum }_{k = 1}^{N / 2 - 1} DFT ( {I}_{0 j} [ n ] ) {e}^{\frac{j 2 π kn}{N}} + DFT ( {I}_{0 j} [ N / 2 ] ) {e}^{j π n} + {\sum }_{k = 1 N / 2}^{N - 1} DFT ( {I}_{0 j} [ n ] ) {e}^{\frac{j 2 π kn}{N}}$$

wherein I₀ⱼ[n] is the discrete time series of the zero-sequence current signal at the j-th of the monitoring points, DFT (I₀ⱼ[0]) is a result of a discrete Fourier transform and indicating a frequency component of the signal in a frequency domain, N is an actual sampling point of the intercepted signal I₀ⱼ, K is a frequency index, indicating a number of the current frequency component, and the value range is 1≤k<N/2−1, n is a index of a discrete point in time series, and the value range is 1≤n≤N;

$${e}^{\frac{j 2 π kn}{N}}$$

is a phase rotation factor in Fourier transform and indicating the phase information of frequency components; and taking a real part of the above results as a signal component for subsequent feature extraction.

In an embodiment, the extraction of the first natural mode function includes:
ensuring length N of the zero-sequence current signal I₀ⱼ to be even, and when the length N is odd, discarding the last sampling value to make the length N being always even;
calculating the characteristic function of a frequency component after Fourier transform according to the following formula:

$${f}_{i} [ n ] {e}^{{jϕ}_{i} [ n ]} = {\sum }_{k = {N}_{t - 1} + 1}^{{N}_{t}} DFT ( {I}_{0 k} [ n ] ) {e}^{\frac{j 2 π kn}{N}} , i = 1 , 2 , ... , N / 2 - 1$$

wherein fᵢ[n] is an amplitude of an i-th frequency component, φᵢ[n] is a phase angle of the i-th frequency component, DFT(I₀ₖ[n]) is the result of a discrete Fourier transform and indicating the frequency component of the signal in frequency domain,

$${e}^{\frac{j 2 π kn}{N}}$$

is a phase rotation factor;
ensuring φᵢ[n+1]≥φᵢ[n−1] and N/2≥Nᵢ+1, and then taking the real part of the above formula to obtain N/2−1 characteristic functions, denoting as IMFₘ, m=1, 2, . . . , n/2−1; and taking the first natural mode function IMF₁, and directly using to reconstruct an original signal and extracting a high impedance fault feature, and recording it as

$${IMF}_{1} = {I}_{0 j}^{Re} .$$

In an embodiment, in the S4 step, the constructing the feature vector includes:
S401, designing a set of mutually orthogonal vector groups \vec{a} and \vec{b} for signal projection, and the expression is:

$$\text{?} \begin{matrix}{a}^{v} = \{ {A}_{1} cos ( {w}_{0} {t}_{k} + j ) \} \\ {b}^{v} = \{ {A}_{2} cos ( {w}_{0} {t}_{k} + j - \frac{p}{2} ) \} \\ {A}_{1} \times {A}_{2} > 0\end{matrix}$$

$$\text{?} \text{indicates text missing or illegible when filed}$$

wherein w₀ is an angular frequency of a power grid, A₁, A₂, j Î R, tₖ Î [t_{f}, t_{f}+0.5T×P], P and k are positive integers, tₖ₊₁−tₖ=1/f_{c}, and f_{c} is an actual sampling frequency of a current sensor;
a typical values are: A₁=A₂=1, j=0, f_{c}=10 kHz, tₖ₊₁−tₖ=10⁻⁴; and
S402, projecting the first natural mode function signal to the vector group, taking P=1 and f_{c} to the actual sampling frequency of the current sensor, intercepting the first natural mode function calculated at all of the monitoring points corresponding to [t_{f}, t_{f}+0.5T] time period, recording the first natural mode function obtained at a j-th monitoring point as

$${I}_{0 j}^{Re , 0.5 T} ,$$

and projecting

$${I}_{0 j}^{Re , 0.5 T}$$

to the orthogonal vector group proposed in step S401 to obtain the projection result:

$$\text{?} \begin{matrix}{a}^{'} {I}_{0 j}^{Re , 0.5 T} , {a}^{v} \tilde{n} = arccos \frac{{I}_{0 j}^{Re , 0.5 T} \text{?}}{‖ {I}_{0 j}^{Re , 0.5 T} ‖ \text{?} ‖ {a}^{v} ‖} \\ {a}^{'} {I}_{0 j}^{Re , 0.5 T} , {b}^{v} \tilde{n} = arccos \frac{{I}_{0 j}^{Re , 0.5 T} \text{?}}{‖ {I}_{0 j}^{Re , 0.5 T} ‖ \text{?} ‖ {b}^{v} ‖}\end{matrix} .$$

$$\text{?} \text{indicates text missing or illegible when filed}$$

In an embodiment, in the S4 step, a result of a feature vector generation is expressed in polar coordinates: S403, obtaining a set of three-dimensional vectors as follows:

$${M}_{j} = \text{?} \vert {I}_{0 j}^{Re , 0.5 T} \vert {a}^{'} {I}_{0 j}^{Re , 0.5 T} , {a}^{v} \tilde{n} {a}^{'} {I}_{0 j}^{Re , 0.5 T} , {b}^{v} \tilde{n} + p \text{?} \text{?}$$

$$\text{?} \text{indicates text missing or illegible when filed}$$

which can be correspondingly expressed as J pairs of vector groups in polar coordinates:

$$\text{?} \begin{matrix}{P}_{j , {a}^{v}}^{v} = ( \vert {I}_{0 j}^{Re , 0.5 T} \vert , {a}^{'} {I}_{0 j}^{Re , 0.5 T} , {a}^{v} \tilde{n} ) \\ {P}_{j , {b}^{v}}^{v} = ( \vert {I}_{0 j}^{Re , 0.5 T} \vert , {a}^{'} {I}_{0 j}^{Re , 0.5 T} , {b}^{v} \tilde{n} + p )\end{matrix}$$

$$\text{?} \text{indicates text missing or illegible when filed}$$

S404, taking all j=1, 2, 3, . . . , J, if the following inequality can be established:

$$max \{ {a}^{'} {I}_{0 j}^{Re , 0.5 T} , {a}^{v} \tilde{n} \} - min \{ {a}^{'} {I}_{0 j}^{Re , 0.5 T} , {a}^{v} \tilde{n} \} > max \{ {a}^{'} {I}_{0 j}^{Re , 0.5 T} , {b}^{v} \tilde{n} \} - min \{ {a}^{'} {I}_{0 j}^{Re , 0.5 T} , {b}^{v} \tilde{n} \}$$

wherein the orientation quantity group

$$\{ {{P}^{V}}_{j , {a}^{V}} \}$$

is used as the characteristic vector group for judging the high impedance fault, otherwise, the orientation quantity group

$$\{ {P}_{j , {b}^{v}}^{v} \}$$

is used as the feature vector group for judging the high impedance fault;
S405, recording the feature vector group obtained in the S404 step to judge the high impedance fault as

$$\{ {P}_{j}^{{v}_{0.5 T}} \} ;$$

and
S406, repeating the steps S402-S405 with P=2 and P=4, respectively, and obtaining two other groups of the feature vector groups for

$$\{ {P}_{j}^{{v}_{T}} \} and \{ {P}_{j}^{{v}_{2 T}} \}$$

judging the high impedance fault.

In an embodiment, in the S5 step, the fusing feature and clustering analysis includes:
S501, clustering generated direction vector groups

$$\{ {P}_{j}^{{v}_{0.5 T}} \} , \{ {P}_{j}^{{v}_{1 T}} \} and \{ {P}_{j}^{{v}_{2 T}} \}$$

by a fuzzy clustering algorithm, and the number of clustering categories is 2, representing the upstream and downstream of the fault point respectively;
S502, calculating contour coefficients corresponding to the above three groups of clustering results, and recording them as SC_{0.5T}, SC_{1T} and SC_{2T}, a contour coefficient formula is as follows:

$$S ( i ) = \frac{b ( i ) - a ( i )}{max \{ a ( i ) , b ( i ) \}} ;$$

wherein a(i) represents a cohesion of sample points, which is calculated as follows:

$$a ( i ) = \frac{1}{n - 1} {\sum }_{j \neq i}^{n} distance ( i , j )$$

wherein j represents other sample point in the same class as sample i, and distance represents distance between i and j, and the smaller a(i) means that the class is more compact, the calculation method of b(i) is similar to that of a(i), but it is necessary to traverse other clusters to get multiple values {b₁(i), b₂(i), b₃(i), . . . , bₘ(i)}, and choose the smallest value as the final result;

$$S ( i ) \text{:} S ( i ) = \{ \begin{matrix}1 - \frac{a ( i )}{b ( i )} & a ( i ) < b ( i ) \\ 0 & a ( i ) = b ( i ) \\ \frac{b ( i )}{a ( i )} - 1 & a ( i ) > b ( i )\end{matrix}$$

from the above formula, finding that:
when a(i)<b(i), distance within a class is less than the distance between classes, the clustering result will be more compact, and a value of S will approach 1, and the closer to 1, the contour will be more obvious; and
when a(i)>b(i), the distance within a class is greater than the distance between classes, indicating that the clustering result is very loose, and the value of S will approach −1, and the closer to −1, the clustering effect will be worse; and
S503, comparing the sizes of the three cluster results, take one of the three cluster results corresponding to a maximum value as the basis for judging the fault location, and determining a section location where the fault is located in combination with an actual network topology.

In the second aspect, the present application adopts the following technical solutions.

A system for quickly locating the high impedance fault in distribution network based on directional frequency scanning, wherein the system is used for a high-speed location method of the high impedance fault in the distribution network based on the directional frequency scanning, including: signal acquisition module, and the signal acquisition module is used for acquiring a zero-sequence current signal I₀ⱼ collected by each of monitoring points of the distribution network and a bus zero-sequence voltage signal U₀ of the distribution network to provide basic data for fault location; fault time determination module, and the fault time determination module is used for analyzing the bus zero-sequence voltage signal U₀ and determining an accurate fault occurrence time t_{f} by setting a threshold value and a reverse search algorithm; feature extraction module, and the feature extraction module is used for performing discrete Fourier transform on the zero-sequence current signal I₀ⱼ and extracting a first natural mode function for reconstructing a fault signal feature; feature vector construction module, and the feature vector construction module is used for generating a reference vector in a high-dimensional space, projecting a first natural mode function to an orthogonal vector group, constructing a three-dimensional feature vector, and intuitively representing a fault feature; and feature fusion and analysis module, and the feature fusion and analysis module is used for analyzing a direction vector based on a fuzzy clustering algorithm, calculating a contour coefficient, and locating a fault section in combination with a network topology.

In the third aspect, the present application adopts the following technical solutions.

A computer device includes a memory; a processor; and a computer program stored in the memory and operable on the processor, wherein the processor executes the computer program to realize a high-speed location method of high impedance fault in distribution network based on directional frequency scanning.

In the fourth aspect, the present application adopts the following technical solutions.

A readable storage medium, wherein a computer program is stored on the readable storage medium, and the computer program is executed by a processor to realize a high-speed location method of high impedance fault in distribution network based on directional frequency scanning.

### Beneficial Effects of the Present Application

1. In this application, according to the method for constructing the virtual reference direction through orthogonal vector groups, voltage transformers are not required to be installed at all measuring points, and in addition, the distributed parallel computing mode can realize local rapid processing of fault data without uploading complete data to the master station, so that the hardware investment and maintenance cost are reduced, the dependence on physical hardware is reduced, and the fault detection speed is greatly improved.
2. In this application, the processed three-dimensional feature vector is returned instead of the complete sampling data, so that compared with the traditional method, the data transmission amount and communication delay are significantly reduced, and the response speed of the system is improved. This is very important for real-time and efficient fault location, especially for large-scale distribution networks that need rapid feedback.
3. In this application, the first natural mode function (IMF₁) is extracted by adaptive Fourier decomposition, so that the original fault signal can be effectively reconstructed in the noise background. This can ensure that the characteristics of high impedance faults are accurately extracted, improve the fault identification rate, and maintain high accuracy even in complex noise environment.
4. In this application, edge computing nodes are deployed at each sampling point, each node independently completes data feature extraction and computing tasks, and the distributed parallel computing is used to accelerate processing, thus effectively reducing the computing burden of the master station. This design improves the real-time, reliability and efficiency of the whole system, and is especially suitable for application scenarios that require strict fault response time.

### BRIEF DESCRIPTION OF THE DRAWINGS

FIG. 1 is a flowchart of high-speed location method of high impedance fault in distribution network based on directional frequency scanning of the present application.

FIG. 2 is a schematic diagram of seven zero-sequence current sampling points distributed in a 10 kV medium-voltage distribution system of the present application.

FIG. 3 is a schematic diagram of an ideal zero-sequence current sampling signal without considering the influence of noise interference at each measuring point of the present application.

FIG. 4 is a schematic diagram of characteristic vector groups in polar coordinates under different fault angles of the present application.

FIG. 5 is a schematic diagram of the polar coordinate form feature vector group under the interference of −2.8 dB strong noise of the present application.

### DETAILED DESCRIPTION OF THE EMBODIMENTS

In order to enable those in the technical field better understand the solutions of the present application, the technical solutions in the embodiment of the present application will be described clearly and completely with the attached drawings. Obviously, the described embodiment is only a part of the embodiment of the present application, but not the whole embodiment. Based on the embodiment in this application, all other embodiment obtained by ordinary technicians in this field without creative work should belong to the protection scope of this application.

### Embodiment 1

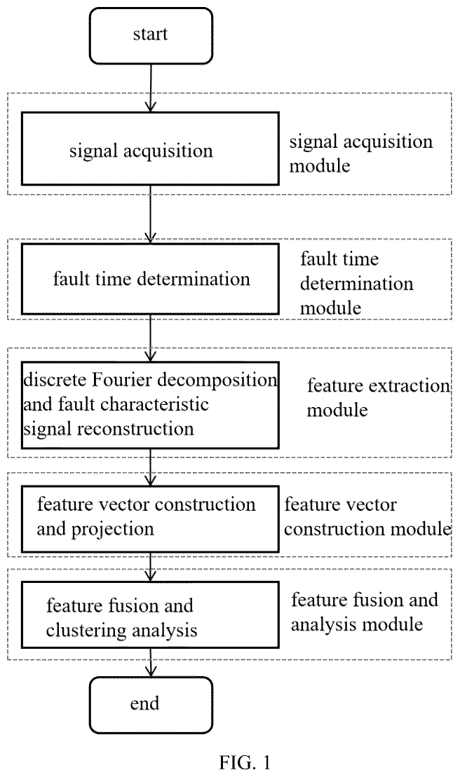

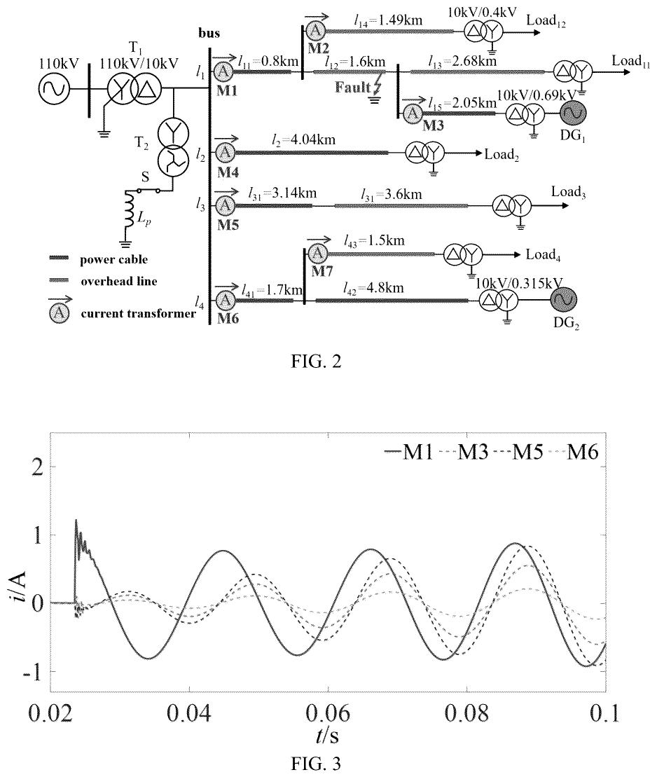

Referring to FIG. 1-5, in the first embodiment of the present application, the present application provides a high-speed location method of high impedance fault in distribution network based on directional frequency scanning, including the following steps:
S1, collecting signal: intercepting a zero-sequence current signal I₀ⱼ collected by each of monitoring points of the distribution network and a bus zero-sequence voltage signal U₀ of the distribution network, wherein j is a corresponding serial number of the monitoring points, [t_{f}−T, t_{f}+5T] is an interception time of the zero-sequence current signal, t_{f} is a fault occurrence time, and T is a power frequency cycle of the power network;
S2, determining the fault occurrence time: determining the fault occurrence time t_{f} by analyzing the bus zero-sequence voltage signal U₀;
S3, decomposing discrete Fourier and reconstructing a fault characteristic signal: using the discrete Fourier decomposition to construct a directional frequency scanning strategy for the zero-sequence current signal I₀ⱼ collected by the monitoring points, and extracting a first natural mode function to directly reconstruct a original fault signal;
S4, constructing and projecting a feature vector: constructing a reference orthogonal vector group in a high-dimensional space, and projecting a first natural mode function signal to the reference orthogonal vector group respectively to generate a three-dimensional feature vector;
S5, fusing feature and clustering analysis: distinguishing the upstream and downstream of a fault point by a clustering algorithm and locating a fault area by a clustering result based on the feature vector of a plurality of time scales.

Specifically, the flow of the whole method is described, including signal acquisition, fault time determination, discrete Fourier transform and feature extraction, feature vector construction and projection, feature fusion and cluster analysis. Through directional frequency scanning and the extraction of the first natural mode function (IMF1), this method has high fault feature extraction ability in noisy environment, and can reliably capture weak high impedance fault signal features. The edge computing method disperses the data processing task to each sampling point, which greatly reduces the data transmission volume and the calculation burden of the central station and significantly improves the response speed; There is no need to install expensive voltage transformers at all monitoring points, and the fault location with low cost and high accuracy is realized by relying on the calculation of virtual reference direction. Using multi-time scale analysis and fuzzy clustering technology can effectively improve the robustness of fault detection and location, and avoid misjudgment caused by the randomness of data at a single time point.
in the S2 step, the determination of the fault occurrence time includes:
S201, taking the time stamp tₛₑₜ corresponding to the sampling sequence number satisfying U₀=0.15Uₙ for the first time as a benchmark; and
S202, in the bus zero-sequence voltage sampling sequence before 100T of tₛₑₜ, the sampling point that first satisfies the following conditions is reverse searched and designated as t_{f}:

$$\vert U ( z ) - U ( z - 4 ) \vert < 9 \&\& \vert U ( z - 15 ) - U ( z - 30 ) \vert < 4$$

wherein U(z) is a discrete sampling value of the bus zero-sequence voltage, z is a index number of the corresponding sampling time, U(z−4) is the discrete sampling value of bus zero-sequence voltage with the corresponding index number z−4, U(z−15) is the discrete sampling value of bus zero-sequence voltage with corresponding index number z−15, and U(z−30) is the discrete sampling value of bus zero-sequence voltage with corresponding index number z−30.

Specifically, it uses a specific zero-sequence voltage threshold condition U₀=0.15Uₙ as a reference, and finally determines the exact time t_{f} when the fault occurs by reversely searching the sampling points that meet the specific conditions.

Its functions and effects include simplify calculation: through simple voltage threshold comparison, quickly lock the time range of potential faults and reduce the computational complexity, improve accuracy, reverse search combined with multiple constraints can effectively avoid time misjudgment caused by random noise or false measurement, enhance adaptability, this method is not only suitable for high impedance faults, but also suitable for judging other types of faults, and has strong universality.

The decomposing discrete Fourier includes: performing Fourier expansion on discrete time series I₀ⱼ[n] with length N:

$${I}_{0 j} [ n ] = DFT ( {I}_{0 j} [ 0 ] ) + {\sum }_{k = 1}^{N / 2 - 1} DFT ( {I}_{0 j} [ n ] ) {e}^{\frac{j 2 π k n}{N}} + DFT ( {I}_{0 j} [ N / 2 ] ) {e}^{j π n} + {\sum }_{k = N / 2 + 1}^{N - 1} DFT ( {I}_{0 j} [ n ] ) {e}^{\frac{j 2 π k n}{N}}$$

wherein I₀ⱼ[n] is the discrete time series of the zero-sequence current signal at the j-th of the monitoring points, DFT (I₀ⱼ[0]) is a result of a discrete Fourier transform and indicating a frequency component of the signal in a frequency domain, N is an actual sampling point of the intercepted signal I₀ⱼ, K is a frequency index, indicating a number of the current frequency component, and the value range is 1≤k<N/2−1, n is a index of a discrete point in time series, and the value range is 1≤n≤N;

$${e}^{\frac{j 2 π k n}{N}}$$

is a phase rotation factor in Fourier transform and indicating the phase information of frequency components; and taking a real part of the above results as a signal component for subsequent feature extraction.

Specifically, the realization method of discrete Fourier transform is defined, which is used to extract high-frequency and low-frequency features by expanding and decomposing the frequency components of the signal.

Its function and effect are embodied in multi-band analysis, the zero-sequence current signal is decomposed into frequency components by Fourier transform, which lays the foundation for subsequent feature extraction and analysis; preserving signal characteristics: adopting the method of real part feature extraction can reduce the computational complexity while maintaining the original characteristics of the signal; wide applicability: this step is not only applicable to high impedance fault in distribution network, but also applicable to other fault detection scenarios involving frequency domain analysis.

The extraction of the first natural mode function includes:
ensuring length N of the zero-sequence current signal I₀ⱼ to be even, and when the length N is odd, discarding the last sampling value to make the length N being always even;
calculating the characteristic function of a frequency component after Fourier transform according to the following formula:

$${f}_{i} [ n ] {e}^{j {ϕ}_{i} [ n ]} = {\sum }_{k = {N}_{i - 1} + 1}^{{N}_{i}} DFT ( {I}_{0 k} [ n ] ) {e}^{\frac{j 2 π k n}{N}} , i = 1 , 2 , … , N / 2 - 1$$

wherein fᵢ[n] is an amplitude of an i-th frequency component, φᵢ[n] is a phase angle of the i-th frequency component, DFT (I₀ₖ[n]) is the result of a discrete Fourier transform and indicating the frequency component of the signal in frequency domain,

$${e}^{\frac{j 2 π k n}{N}}$$

is a phase rotation factor;
ensuring φᵢ[n+1]≥φᵢ[n−1] and N/2≥Nᵢ+1, and then taking the real part of the above formula to obtain N/2−1 characteristic functions, denoting as IMFₘ, m=1, 2, . . . , n/2−1; and taking the first natural mode function IMF₁, and directly using to reconstruct an original signal and extracting a high impedance fault feature, and recording it as

$${IMF}_{1} = {I}_{0 , j}^{Re} .$$

Specifically, the extraction process of the first natural mode function (IMF₁) is described, the core of which is to obtain the main characteristic components of the signal through frequency scanning.

Its functions and effects include: signal feature enhancement: as the first mode of the signal, IMF₁ contains the most critical high-frequency components in the signal, which can effectively enhance the fault features;
Noise reduction ability: through the selection of frequency monotonic conditions, the frequency components unrelated to faults are eliminated, and noise interference is effectively suppressed;
Optimized feature extraction: adaptive Fourier decomposition technology can accurately extract the core features of high impedance faults in complex environment.

In the S4 step, the constructing the feature vector includes:
S401, designing a set of mutually orthogonal vector groups \vec{a} and \vec{b} for signal projection, and the expression is:

$$\begin{matrix}{a}^{V} = \{ {A}_{1} cos ( {w}_{0} {t}_{k} + j ) \} \\ {b}^{V} = \{ {A}_{2} cos ( {w}_{0} {t}_{k} + j - \frac{p}{2} ) \} \\ {A}_{1} \times {A}_{2} > 0\end{matrix}$$

wherein w₀ is an angular frequency of a power grid, A₁, A₂, j Î R, tₖ Î [t_{f}, t_{f}+0.5T×P], P and k are positive integers, tₖ₊₁−tₖ=1/f_{c}, and f_{c} is an actual sampling frequency of a current sensor;
a typical values are: A₁=A₂=1, j=0, f_{c}=10 kHz, tₖ₊₁−tₖ=10⁻⁴; and
S402, projecting the first natural mode function signal to the vector group, taking P=1 and f_{c} to the actual sampling frequency of the current sensor, intercepting the first natural mode function calculated at all of the monitoring points corresponding to [t_{f}, t_{f}+0.5T] time period, recording the first natural mode function obtained at a j-th monitoring point as

$${I}_{0 j}^{Re , 0.5 T} ,$$

and projecting

$${I}_{0 j}^{Re , 0.5 T}$$

to the orthogonal vector group proposed in step S401 to obtain the projection result:

$$\begin{matrix}á {I}_{0 j}^{Re , 0.5 T} , {añ}^{V} = arc cos \frac{{I}_{0 j}^{Re , 0.5 T} {g a}^{V}}{‖ {I}_{0 j}^{Re , 0.5 T} ‖ , ‖ {a}^{V} ‖} \\ á {I}_{0 j}^{Re , 0.5 T} , {bñ}^{V} = arc cos \frac{{I}_{0 j}^{Re , 0.5 T} {g b}^{V}}{‖ {I}_{0 j}^{Re , 0.5 T} ‖ , ‖ {b}^{V} ‖}\end{matrix} .$$

Specifically, the construction method of feature vectors is proposed. By designing orthogonal vector groups A and B, the real signal of the first natural mode function (IMF₁) is projected to generate a feature vector with physical significance.

Its functions and effects include:
Intuitive representation: through the projection of orthogonal vector group, the complex signal is decomposed into geometric features that are easy to analyze, which improves the intuition of fault analysis;
Spatial characteristics enhancement: the feature vector shows the distribution characteristics of fault signals in high-dimensional space, which provides high-dimensional information support for subsequent fault location;
Reduce complexity: Orthogonal projection reduces the amount of original signal data and optimizes the calculation efficiency while maintaining signal integrity.

In the S4 step, a result of a feature vector generation is expressed in polar coordinates: S403, obtaining a set of three-dimensional vectors as follows:

$${M}_{j} = \text{?} \vert {I}_{0 j}^{Re , 0.5 T} \vert á {I}_{0 j}^{Re , 0.5 T} , {añ}^{V} á {I}_{0 j}^{Re , 0.5 T} , {bñ}^{V} + p \text{?} ;$$

$$\text{?} \text{indicates text missing or illegible when filed}$$

which can be correspondingly expressed as J pairs of vector groups in polar coordinates:

$$\begin{matrix}{P}_{j , a}^{{V}_{v}} = ( \vert {I}_{0 j}^{Re , 0.5 T} \vert , á {I}_{0 j}^{Re , 0.5 T} , {añ}^{V} ) \\ {P}_{j , b}^{{V}_{v}} = ( \vert {I}_{0 j}^{Re , 0.5 T} \vert , á {I}_{0 j}^{Re , 0.5 T} , {bñ}^{V} + p )\end{matrix}$$

S404, taking all j=1, 2, 3, . . . , J, if the following inequality can be established:

$$max \{ á {I}_{0 j}^{Re , 0.5 T} , {a}^{V} \tilde{n} \} - min \{ á {I}_{0 j}^{Re , 0.5 T} , {a}^{V} \tilde{n} \} > max \{ á {I}_{0 j}^{Re , 0.5 T} , {b}^{V} \tilde{n} \} - min \{ á {I}_{0 j}^{Re , 0.5 T} , {b}^{V} \tilde{n} \}$$

the orientation quantity group

$$\{ {{P}^{V}}_{j , {a}^{V}} \}$$

is used as the characteristic vector group for judging the high impedance fault, otherwise, the orientation quantity group

$$\{ {{P}^{V}}_{j , {b}^{V}} \}$$

is used as the feature vector group for judging the high impedance fault;
S405, recording the feature vector group obtained in the S404 step to judge the high impedance fault as

$$\{ {{P}^{V}}_{j}^{0.5 T} \} ;$$

and
S406, repeating the steps S402-S405 with P=2 and P=4, respectively, and for judging the high obtaining two other groups

$$\{ {{P}^{V}}_{j}^{T} \} and \{ {{P}^{V}}_{j}^{2 T} \}$$

the feature vector groups impedance fault.

Specifically, the calculation methods of direction vector and three-dimensional feature vector are further refined, and the polar coordinate representation of feature vector is proposed.

Its functions and effects include: high-precision modeling: accurately capture the directional characteristics of fault signals through the calculation of direction vectors; geometric representation optimization: the polar coordinate representation of three-dimensional feature vectors enhances the spatial distribution information of signal features and lays the foundation for clustering analysis; improve robustness: polar coordinate representation avoids the deviation caused by coordinate system selection and improves the expression ability of fault signal characteristics.

In the S5 step, the fusing feature and clustering analysis includes:
S501, clustering generated direction vector groups

$$\{ {{P}^{V}}_{j}^{0.5 T} \} , \{ {{P}^{V}}_{j}^{1 T} \} and \{ {{P}^{V}}_{j}^{2 T} \}$$

by a fuzzy clustering algorithm, and the number of clustering categories is 2, representing the upstream and downstream of the fault point respectively;
S502, calculating contour coefficients corresponding to the above three groups of clustering results, and recording them as SC_{0.5T}, SC_{1T} and SC_{2T}, a contour coefficient formula is as follows:

$$S ( i ) = \frac{b ( i ) - a ( i )}{max \{ a ( i ) , b ( i ) \}} ;$$

wherein a(i) represents a cohesion of sample points, which is calculated as follows:

$$a ( i ) = \frac{1}{n - 1} {\sum }_{j \neq i}^{n} distance ( i , j )$$

wherein j represents other sample point in the same class as sample i, and distance represents distance between i and j, and the smaller a(i) means that the class is more compact, the calculation method of b(i) is similar to that of a(i), but it is necessary to traverse other clusters to get multiple values {b₁(i), b₂(i), b₃(i), . . . , bₘ(i)}, and choose the smallest value as the final result;

$$S ( i ) : S ( i ) = \{ \begin{matrix}1 - \frac{a ( i )}{b ( i )} & a ( i ) < b ( i ) \\ 0 & a ( i ) = b ( i ) \\ \frac{b ( i )}{a ( i )} - 1 & a ( i ) > b ( i )\end{matrix}$$

from the above formula, finding that:
when a(i)<b(i), distance within a class is less than the distance between classes, the clustering result will be more compact, and a value of S will approach 1, and the closer to 1, the contour will be more obvious; and
when a(i)>b(i), the distance within a class is greater than the distance between classes, indicating that the clustering result is very loose, and the value of S will approach −1, and the closer to −1, the clustering effect will be worse;
S503, comparing the sizes of the three cluster results, take one of the three cluster results corresponding to a maximum value as the basis for judging the fault location, and determining a section location where the fault is located in combination with an actual network topology.

Specifically, a feature fusion and analysis method based on fuzzy clustering algorithm (FCM) and contour coefficient calculation is defined in detail.

Its functions and effects include: fault section judgment: by clustering the direction vector, the upstream and downstream distribution of fault points can be quickly identified; optimization of classification effect: the introduction of contour coefficient can quantify the clustering effect and ensure the accuracy of classification results; combining the network topology: combining the clustering results with the network topology structure to further accurately locate the fault section; computational flexibility: fuzzy clustering algorithm has strong adaptability and can handle the distribution of feature vectors in different scenes.

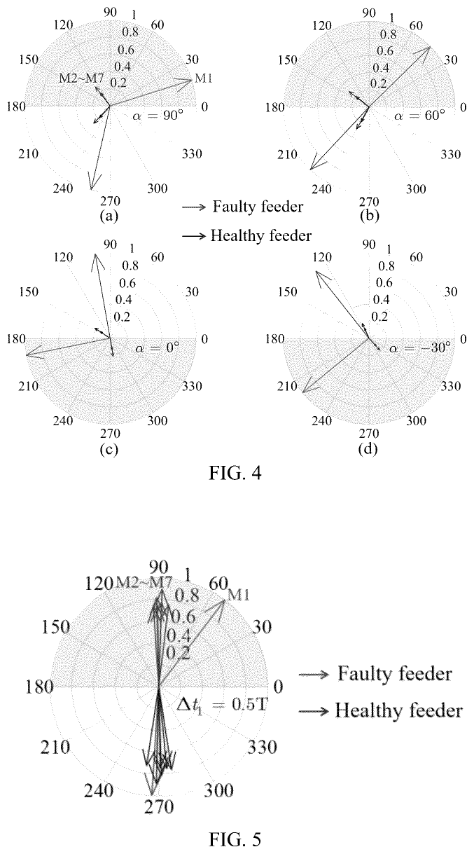

FIG. 4 shows the polar coordinate form feature vector groups (a) a=90°. (b) a=60°. (c) a=0°. (d) a=−30° under different fault angles, and the vector group with light green shading is the final selected feature vector group for judging high impedance fault, and the other group must be discarded.

### Embodiment 2

Referring to FIG. 1, in the second embodiment of the present application, the present application provides a system for quickly locating the high impedance fault in distribution network based on directional frequency scanning, wherein the system is used for a high-speed location method for the high impedance fault in the distribution network based on the directional frequency scanning, including: signal acquisition module, and the signal acquisition module is used for acquiring a zero-sequence current signal I₀ⱼ collected by each of monitoring points of the distribution network and a bus zero-sequence voltage signal U₀ of the distribution network to provide basic data for fault location; fault time determination module, and the fault time determination module is used for analyzing the bus zero-sequence voltage signal U₀ and determining an accurate fault occurrence time t_{f} by setting a threshold value and a reverse search algorithm; feature extraction module, and the feature extraction module is used for performing discrete Fourier transform on the zero-sequence current signal I₀ⱼ and extracting a first natural mode function for reconstructing a fault signal feature; feature vector construction module, and the feature vector construction module is used for generating a reference vector in a high-dimensional space, projecting a first natural mode function to an orthogonal vector group, constructing a three-dimensional feature vector, and intuitively representing a fault feature; and feature fusion and analysis module, and the feature fusion and analysis module is used for analyzing a direction vector based on a fuzzy clustering algorithm, calculating a contour coefficient, and locating a fault section in combination with a network topology.

### Embodiment 3

In the third embodiment of the present application, the present application provides a computer device includes a memory; a processor; and a computer program stored in the memory and operable on the processor, wherein the processor executes the computer program to realize a high-speed location method for high impedance fault in distribution network based on directional frequency scanning.

### Embodiment 4

In the fourth embodiment of the present application, the present application provides a readable storage medium, wherein a computer program is stored on the readable storage medium, and the computer program is executed by a processor to realize a high-speed location method for high impedance fault in distribution network based on directional frequency scanning.

It should be understood that various parts of the present application can be implemented in hardware, software, firmware or a combination thereof. In the above embodiment, a plurality of steps or methods can be realized by software or firmware stored in a memory and executed by an appropriate instruction execution system. For example, if it is implemented in hardware, as in another embodiment, it can be implemented by any one of the following technologies or their combination: a discrete logic circuit with a logic gate for implementing a logic function on a data signal, an application specific integrated circuit with a suitable combination logic gate, a programmable gate array (PGA), a field programmable gate array (FPGA), and the like.

The above is only the preferred embodiment of the present application. If the scope of implementation of the present application cannot be limited, that is, all the equal changes and modifications made according to the scope of this application should still fall within the scope of the present application.

What is claimed is:

1. A high-speed location method for high impedance fault in a distribution network based on directional frequency scanning, comprising:
S1, collecting signal: intercepting a zero-sequence current signal I₀ⱼ collected by each of monitoring points of the distribution network and a bus zero-sequence voltage signal U₀ of the distribution network, wherein j is a corresponding serial number of the monitoring points, [t_{f}−T, t_{f}+5T] is an interception time of the zero-sequence current signal, t_{f} is a fault occurrence time, and T is a power frequency cycle of the power network;
S2, determining the fault occurrence time: determining the fault occurrence time tr by analyzing the bus zero-sequence voltage signal U₀;
S3, decomposing discrete Fourier and reconstructing a fault characteristic signal: using the discrete Fourier decomposition to construct a directional frequency scanning strategy for the zero-sequence current signal I₀ⱼ collected by the monitoring points, and extracting a first natural mode function to directly reconstruct a original fault signal;
S4, constructing and projecting a feature vector: constructing a reference orthogonal vector group in a high-dimensional space, and projecting a first natural mode function signal to the reference orthogonal vector group respectively to generate a three-dimensional feature vector; and
S5, fusing feature and clustering analysis: distinguishing the upstream and downstream of a fault point by a clustering algorithm and locating a fault area by a clustering result based on the feature vector of a plurality of time scales;
wherein in the S4 step, the constructing the feature vector comprises:
S401, designing a set of mutually orthogonal vector groups \vec{a} and \vec{b} for signal projection, and the expression is:
$$\{ \begin{matrix}\vec{a} = \{ {A}_{1} cos ( {ω}_{0} {t}_{k} + φ ) \} \\ \vec{b} = \{ {A}_{2} cos ( {ω}_{0} {t}_{k} + φ - \frac{π}{2} ) \} \\ {A}_{1} \cdot {A}_{2} > 0\end{matrix} ;$$
wherein w₀ is an angular frequency of a power grid, A₁, A₂, φ└R, tₖ∈[t_{f}, t_{f}+0.5T·P], P and k are positive integers, tₖ₊₁−tₖ=1/f_{c}, and f_{c} is an actual sampling frequency of a current sensor;
a typical values are: A₁=A₂=1, j=0, f_{c}=10 kHz, tₖ₊₁−tₖ=10⁻⁴; and
S402, projecting the first natural mode function signal to the vector group, taking P=1 and f_{c} to the actual sampling frequency of the current sensor, intercepting the first natural mode function calculated at all of the monitoring points corresponding to [t_{f}, t_{f}+0.5T] time period, recording the first natural mode function obtained at a j-th monitoring point as
$${I}_{0 j}^{Re , 0.5 T} ,$$
and projecting
$${I}_{0 j}^{Re , 0.5 T}$$
to the orthogonal vector group proposed in step S401 to obtain the projection result:
$$\{ \begin{matrix}{I}_{0 j}^{Re , 0.5 T} , \vec{a} = arccos \frac{{I}_{0 j}^{Re , 0.5 T} \cdot \vec{a}}{‖ {I}_{0 j}^{Re , 0.5 T} ‖ \times ‖ \vec{a} ‖} \\ {I}_{0 j}^{Re , 0.5 T} , \vec{b} = arccos \frac{{I}_{0 j}^{Re , 0.5 T} \cdot \vec{b}}{‖ {I}_{0 j}^{Re , 0.5 T} ‖ \times ‖ \vec{b} ‖}\end{matrix} ;$$
wherein in the S4 step, a result of a feature vector generation is expressed in polar coordinates:
S403, obtaining a set of three-dimensional vectors as follows:
$${M}_{j} = ( {I}_{0 j}^{Re , 0.5 T} , 〈 {I}_{0 j}^{Re , 0.5 T} , \vec{a} 〉 , 〈 {I}_{0 j}^{Re , 0.5 T} , \vec{b} 〉 + π ) ;$$
and the set of three-dimensional vectors can be correspondingly expressed as J pairs of vector groups in polar coordinates:
$$\{ \begin{matrix}{\vec{P}}_{j , \vec{a}} = ( \vert {I}_{0 j}^{Re , 0.5 T} \vert , {I}_{0 j}^{Re , 0.5 T} , \vec{a} ) \\ {\vec{P}}_{j , \vec{b}} = ( \vert {I}_{0 j}^{Re , 0.5 T} \vert , {I}_{0 j}^{Re , 0.5 T} , \vec{b} + π )\end{matrix} ;$$
S404, taking all j=1, 2, 3, . . . , J, if the following inequality can be established:
$$max \{ \text{?} , \text{?} \} - min \{ \text{?} , \text{?} \} > max \{ \text{?} , \text{?} \} - min \{ \text{?} , \text{?} \} ;$$
$$\text{?} \text{indicates text missing or illegible when filed}$$
wherein the orientation quantity group
$$\{ {{P}^{V}}_{j , {a}^{V}} \}$$
is used as the characteristic vector group for judging the high impedance fault, otherwise, the orientation quantity group
$$\{ {{P}^{V}}_{j , {b}^{V}} \}$$
is used as the feature vector group for judging the high impedance fault;
S405, recording the feature vector group obtained in the S404 step to judge the high impedance fault as
$$\{ {{P}^{V}}_{j}^{0.5 T} \} ;$$
and
S406, repeating the steps S402-S405 with P=2 and P=4, respectively, and obtaining two other groups of the feature vector groups
$$\{ {{P}^{V}}_{j}^{T} \} and \{ {{P}^{V}}_{j}^{2 T} \}$$
for judging the high impedance fault.

2. The high-speed location method of claim 1, wherein in the S2 step, the determination of the fault occurrence time comprises:
S201, taking the time stamp tₛₑₜ corresponding to the sampling sequence number satisfying U₀=0.15Un for the first time as a benchmark; and
S202, in the bus zero-sequence voltage sampling sequence before 100T of tₛₑₜ, the sampling point that first satisfies the following conditions is reverse searched and designated as t_{f}:
$$\vert U ( z ) - U ( z - 4 ) \vert < 9 \&\& \vert U ( z - 15 ) - U ( z - 30 ) \vert < 4$$
wherein U(z) is a discrete sampling value of the bus zero-sequence voltage, z is a index number of the corresponding sampling time, U(z−4) is the discrete sampling value of bus zero-sequence voltage with the corresponding index number z−4, U(z−15) is the discrete sampling value of bus zero-sequence voltage with corresponding index number z−15, and U(z−30) is the discrete sampling value of bus zero-sequence voltage with corresponding index number z−30.

3. The high-speed location method of claim 1, wherein the decomposing discrete Fourier comprises:
performing Fourier expansion on discrete time series I₀ⱼ[n] with length N:
$${I}_{0 j} [ n ] = DFT ( {I}_{0 j} [ 0 ] ) + {\sum }_{k = 1}^{N / 2 - 1} DFT ( {I}_{0 j} [ n ] ) {e}^{\frac{j 2 π kn}{N}} + DFT ( {I}_{0 j} [ N / 2 ] ) {e}^{j π n} + {\sum }_{k = N / 2 + 1}^{N - 1} DFT ( {I}_{0 j} [ n ] ) {e}^{\frac{j 2 π kn}{N}}$$
wherein I₀ⱼ[n] is the discrete time series of the zero-sequence current signal at the j-th of the monitoring points, DFT(I₀ⱼ[0]) is a result of a discrete Fourier transform and indicating a frequency component of the signal in a frequency domain, N is an actual sampling point of the intercepted signal I₀ⱼ, K is a frequency index, indicating a number of the current frequency component, and the value range is 1≤k<N/2−1, n is a index of a discrete point in time series, and the value range is 1≤n≤N;
$${e}^{\frac{j 2 π kn}{N}}$$
is a phase rotation factor in Fourier transform and indicating the phase information of frequency components; and
taking a real part of the above results as a signal component for subsequent feature extraction.

4. The high-speed location method of claim 1, wherein the extraction of the first natural mode function comprises:
ensuring length N of the zero-sequence current signal I₀ⱼ to be even, and when the length N is odd, discarding the last sampling value to make the length N being always even;
calculating the characteristic function of a frequency component after Fourier transform according to the following formula:
$${f}_{i} [ n ] {e}^{j {ϕ}_{i} [ n ]} = {\sum }_{k = {N}_{i - 1} + 1}^{{N}_{i}} DFT ( {I}_{0 k} [ n ] ) {e}^{\frac{j 2 π kn}{N}} , i = 1 , 2 , … , N / 2 - 1$$
wherein fᵢ[n] is an amplitude of an i-th frequency component, φᵢ[n] is a phase angle of the i-th frequency component, DFT(I₀ₖ[n]) is the result of a discrete Fourier transform and indicating the frequency component of the signal in frequency domain,
$${e}^{\frac{j 2 π kn}{N}}$$
is a phase rotation factor;
ensuring φᵢ[n+1]≥φᵢ[n−1] and N/2≥Nᵢ+1 and then taking the real part of the above formula to obtain N/2−1 characteristic functions, denoting as IMFm, m=1, 2, . . . , n/2−1; and
taking the first natural mode function IMF₁, and directly using to reconstruct an original signal and extracting a high impedance fault feature, and recording it as
$${IMF}_{1} = {l}_{0 j}^{Re} .$$

5-6. (canceled)

7. The high-speed location method of claim 1, wherein in the S5 step, the fusing feature and clustering analysis comprises:
S501, clustering generated direction vector groups
$$\{ {{P}^{V}}_{j}^{0.5 T} \} , \{ {{P}^{V}}_{j}^{1 T} \} and \{ {{P}^{V}}_{j}^{2 T} \}$$
by a fuzzy clustering algorithm, and the number of clustering categories is 2, representing the upstream and downstream of the fault point respectively;
S502, calculating contour coefficients corresponding to the above three groups of clustering results, and recording them as SC_{0.5T}, SC_{1T} and SC_{2T}, a contour coefficient formula is as follows:
$$S ( i ) = \frac{b ( i ) - a ( i )}{max \{ a ( i ) , b ( i ) \}} ;$$
wherein a(i) represents a cohesion of sample points, which is calculated as follows:
$$a ( i ) = \frac{1}{n - 1} {\sum }_{j \neq i}^{n} distance ( i , j )$$
wherein j represents other sample point in the same class as sample i, and distance represents distance between i and j, and the smaller a(i) means that the class is more compact, the calculation method of b(i) is similar to that of a(i), but it is necessary to traverse other clusters to get multiple values {b₁(i), b₂(i), b₃(i), . . . , bₘ(i)}, and choose the smallest value as the final result;
$$S ( i ) :$$
$$S ( i ) = \{ \begin{matrix}1 - \frac{a ( i )}{b ( i )} & a ( i ) < b ( i ) \\ 0 & a ( i ) = b ( i ) \\ \frac{b ( i )}{a ( i )} - 1 & a ( i ) > b ( i )\end{matrix}$$
from the above formula, finding that:
when a(i)<b(i), distance within a class is less than the distance between classes, the clustering result will be more compact, and a value of S will approach 1, and the closer to 1, the contour will be more obvious; and
when a(i)>b(i), the distance within a class is greater than the distance between classes, indicating that the clustering result is very loose, and the value of S will approach −1, and the closer to −1, the clustering effect will be worse; and
S503, comparing the sizes of the three cluster results, take one of the three cluster results corresponding to a maximum value as the basis for judging the fault location, and determining a section location where the fault is located in combination with an actual network topology.

8. A system for quickly locating the high impedance fault in a distribution network based on directional frequency scanning, wherein the system is used for a high-speed location method for the high impedance fault in the distribution network based on the directional frequency scanning according to claim 1, comprising:
signal acquisition module, and the signal acquisition module is used for acquiring a zero-sequence current signal I₀ⱼ collected by each of monitoring points of the distribution network and a bus zero-sequence voltage signal U₀ of the distribution network to provide basic data for fault location;
fault time determination module, and the fault time determination module is used for analyzing the bus zero-sequence voltage signal U₀ and determining an accurate fault occurrence time t_{f} by setting a threshold value and a reverse search algorithm;
feature extraction module, and the feature extraction module is used for performing discrete Fourier transform on the zero-sequence current signal I₀ⱼ and extracting a first natural mode function for reconstructing a fault signal feature;
feature vector construction module, and the feature vector construction module is used for generating a reference vector in a high-dimensional space, projecting a first natural mode function to an orthogonal vector group, constructing a three-dimensional feature vector, and intuitively representing a fault feature; and
feature fusion and analysis module, and the feature fusion and analysis module is used for analyzing a direction vector based on a fuzzy clustering algorithm, calculating a contour coefficient, and locating a fault section in combination with a network topology.

9. A computer device, comprising:
a memory;
a processor; and
a computer program stored in the memory and operable on the processor, wherein the processor executes the computer program to realize a high-speed location method for high impedance fault in a distribution network based on directional frequency scanning according to claim 1.

10. A readable storage medium, wherein a computer program is stored on the readable storage medium, and the computer program is executed by a processor to realize a high-speed location method for high impedance fault in a distribution network based on directional frequency scanning according to claim 1.
